(19) United States
(12) Patent Application Publication
(10) Pub. No.: US 2006/0114728 A1
(43) Pub. Date: Jun. 1, 2006

(54) Data storage device having multiple buffers

(76) Inventors: Chanson Lin, Jhubei City (TW); Yu-Hsien Wang, Jhubei City (TW); Hung Chia Huang, Jhubei City (TW); Po Cheng Fan, Jhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/046,813

(22) Filed: Feb. 1, 2005

(30) Foreign Application Priority Data
Nov. 30, 2004 (TW) 93136888

(51) Int. Cl. G11C 7/10

(52) U.S. Cl. 365/189.05

(57) ABSTRACT

A data storage device having multiple buffers is proposed. When storing data, a controller makes use of a host's bus to select and transmit multiple block data to multiple buffers for temporary storage and then records relevant details. Next, the controller transmits the data from the buffers to a storage connected with the controller. When retrieving data, the controller selects the data from the storage and temporarily stores the data in the buffers and then records relevant details. Subsequently, the controller transmits the data to the host. The controller is used to control the operations of the host, the buffers, and the storage. Multiple buffers are exploited to achieve the maximum bandwidth of the transmission interface of the host to increase the transmission speed.

### BACKGROUND OF THE INVENTION

1. Field of the Invention

The present invention relates to a data storage device and, more particularly, to a data storage device having multiple buffers.

2. Description of Related Art

Along with continual progress of the science and technology, data storage devices have gradually become indispensable things of many people. Various data storage devices have been presented to the public. Therefore, people more and more take seriously how to find one with a high transmission speed among numerous data storage devices.

As shown in FIG. 1, a conventional data storage device comprises a host 10 connected to a controller 12. The host transmits data to be stored to the controller 12. The controller 12 then temporarily stores the data in a buffer 14. Next, the controller 12 transmits the data from the buffer 14 to a storage 16. When retrieving data, the controller 12 temporarily stores the data from the memory 16 to the buffer 14 and then transmits the data from the buffer 14 to the host 10. However, only one of the host 10 and the storage 16 of this data storage device can use the buffer 14 to cause the problem of idling of the other one, hence slowing down the transmission speed.

In order to improve the above problem, another conventional data storage device is proposed, as shown in FIG. 2. This data storage device comprises a host 20 connected to a controller 22. The controller 22 is connected with and controls the operations of two buffers A24 and B26 and a storage 28. The two buffer A24 and B26 are used for temporarily storage of data, while the storage 28 is used to store data. As shown in FIG. 3, when the data storage device starts transmitting data, the host 20 transmits data to the buffer A24 during the period from start to t1. The host 20 then transmits data to the buffer B26 during the period from t1 to t2. Meanwhile, the buffer A24 will transmit data to the storage 28. Next, the host 20 transmits data to the buffer A24 for temporary storage during the period from t2 to t3. Meanwhile, the buffer B26 transmits data to the storage 28. The host 20 then transmits data to the buffer B26 during the period from t3 to t4. Meanwhile, the buffer A24 transmits data to the storage 28. The rest may be deduced by analogy.

Although the transmission speed of the above data storage device slightly increases, the transmission speeds of the host 20 and the storage 28 won't be precisely equal. Therefore, there will also be idle time during switching.

### SUMMARY OF THE INVENTION

An object of the present invention is to provide a data storage device having multiple buffers to achieve the maximum bandwidth of the transmission interface of the host during data transmission. Therefore, the occurrence of idle time will be avoided to increase the transmission speed.

In order to achieve the above object, the present invention proposes a data storage device having multiple buffers. The data storage device comprises a host bus for receiving multiple block data sent from a host, multiple buffers for temporarily storing data, a storage for storing data, a recorder for recording the transmission order and the temporary storage positions of data in the buffers, and a controller connected with and controlling the operations of the host bus, the buffers and the storage.

The various objects and advantages of the present invention will be more readily understood from the following detailed description when read in conjunction with the appended drawing, in which:

### BRIEF DESCRIPTION OF THE DRAWINGS

FIG. 1 is a circuit block diagram of a conventional data storage device;

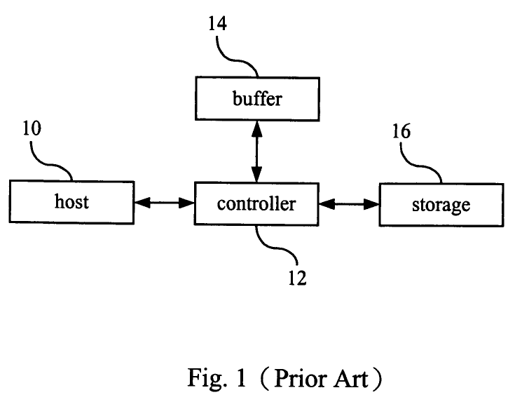

FIG. 2 is a circuit block diagram of another conventional data storage device;

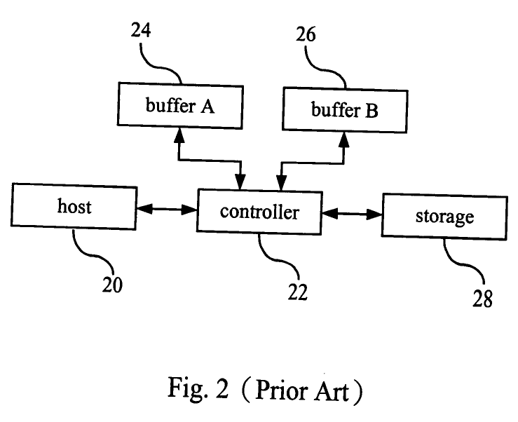

FIG. 3 is a timing diagram of the transmission order of the data storage device in FIG. 2;

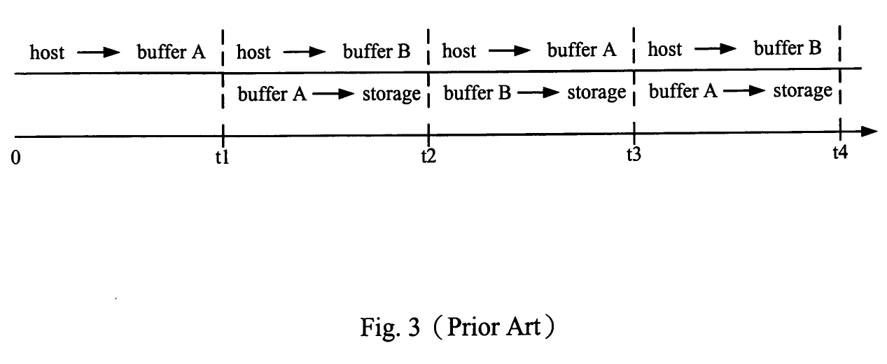

FIG. 4 is a circuit block diagram of a data storage device having multiple buffers of the present invention;

FIG. 5 is a circuit block diagram of a data storage device having multiple buffers according to another embodiment of the present invention;

FIG. 6 is a circuit block diagram of a data storage device having multiple buffers according to yet another embodiment of the present invention;

FIG. 7 is a flowchart of storing data of the data storage device of the present invention;

FIG. 8 is a flowchart of retrieving data of the data storage device of the present invention;

FIG. 9 is a timing diagram of the transmission order of the data storage device having multiple buffers of the present invention;

FIG. 10 is a timing diagram of the transmission order of the data storage device having multiple buffers according to another embodiment of the present invention; and

FIG. 11 is a timing diagram of the transmission order of the data storage device having multiple buffers according to yet another embodiment of the present invention.

### DETAILED DESCRIPTION OF THE PREFERRED EMBODIMENTS

In order to improve the problem of the occurrence of idle time during data transmission of conventional data storage devices, the present invention proposes a data storage device having multiple buffers to achieve the maximum bandwidth of the transmission interface of the host during data transmission so as to increase the transmission speed.

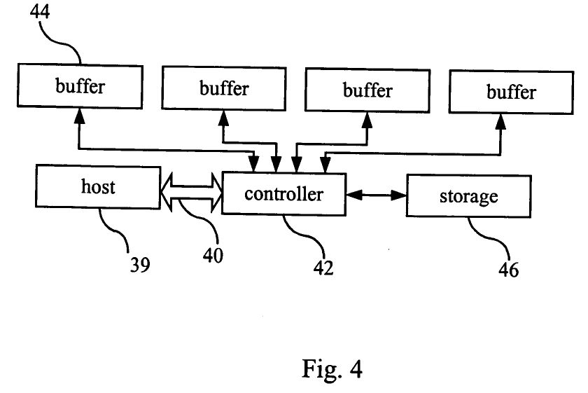

As shown in FIG. 4, a data storage device having multiple buffers of the present invention comprises a host bus 40 for receiving multiple block data sent from a host 39. The host bus 40 is connected to a controller 42. The controller 42 is connected with multiple buffer 44 and a storage 46. The multiple buffers 44 are used for temporary storage of data. The storage is used to store. The controller 42 is used to control the operations of the host bus 40, the buffers 44 and the storage 46.

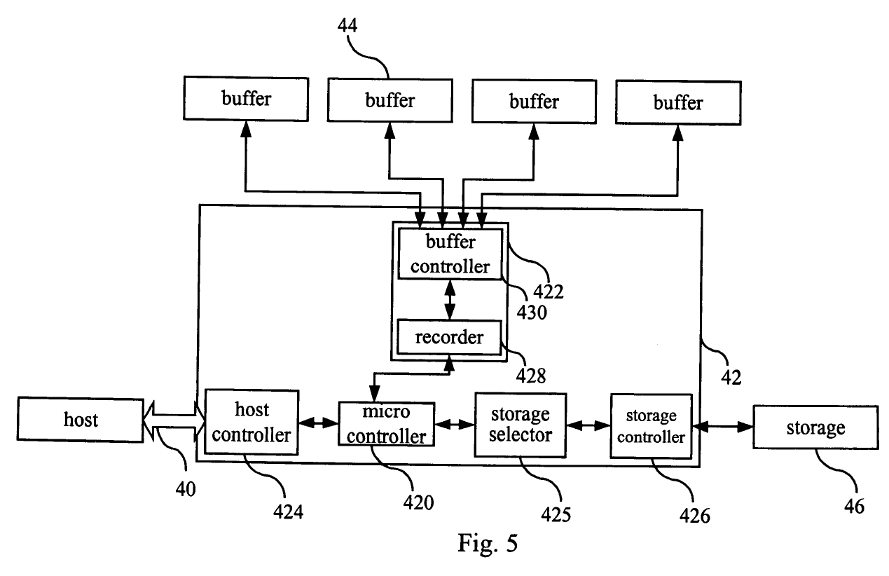

As shown in FIG. 5, the controller 42 comprises a micro controller 420 and a buffer controller 422. The micro controller 420 makes use of a host controller 424 to connect the host bus 40 and makes use of a storage selector 425 and a storage controller 426 to connect the storage 46. The micro controller 420 uses the host controller 424 and the storage controller 426 to control the host bus 40 and the storage 46, respectively. The storage selector 425 selects the storage positions of data in the storage 46. The buffer controller 422 is connected with the micro controller 420 and is used for controlling the operation of the buffers 44. A recorder 428 connected to the micro controller 420 and a buffer selector 420 connected to the buffers 44 and the recorder 428 are disposed in the buffer controller 422. The buffer selector 430 is used to select the temporary storage position of each piece of data in the buffers 44. The recorder 428 records the transmission order and storage position of each piece of data in the buffers 44 and the storage 46. The transmission order and storage positions can be predetermined or randomly selected.

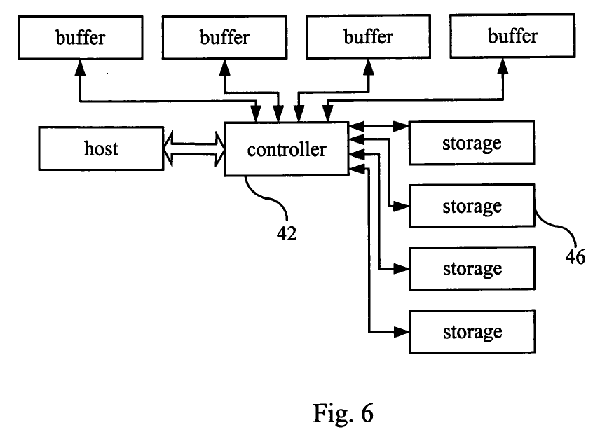

Besides, in addition to installation of a storage 46, multiple storages 46 can be installed, as shown in FIG. 6. The multiple storages 46 are connected to the controller 42 so that data can be stored in different storages 46.

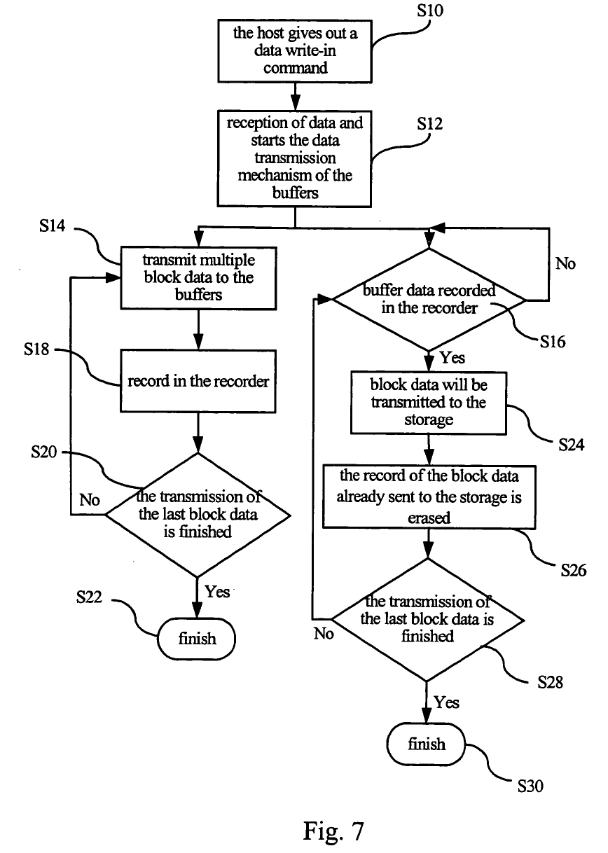

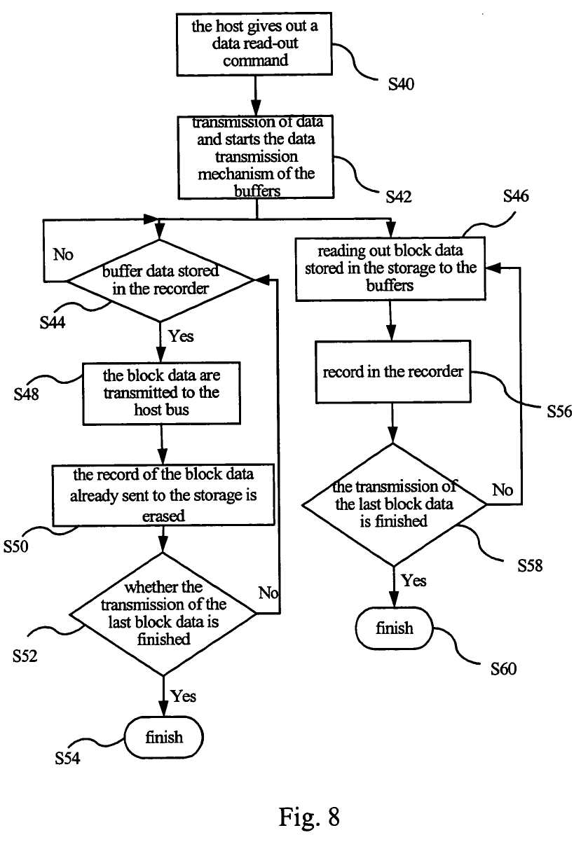

Moreover, the present invention also proposes an access method of the above data storage device. FIGS. 7 and 8 are flowcharts of storing data and retrieving data of the data storage device of the present invention, respectively. It can be clearly seen that the transmissions of the buffers and the storages of the data storage device can be performed simultaneously. Please refer to FIG. 7. First, the host gives out a data write-in command (Step S10). Next, the data is received and the host starts transmitting the data to the buffers (Step S12). The host then uses the host bus to transmit multiple block data to the buffers (Step S14), and whether there are buffer data recorded in the recorder is determined (Step S16). After Step S14, the recorder will record the transmission order and storage positions of the block data (Step S18). Subsequently, whether the transmission of the last block data is finished is determined (Step S20). If the answer is yes, Step S22 is performed to end the flowchart; otherwise, Step S14 is jumped back to for continual transmission of block data. In Step S16, if the answer is no, the determination will be continued. If there are buffer data stored in the recorder, block data will be transmitted to the storage (Step S24). Next, the record of the block data already sent to the storage is erased (Step S26). Finally, whether the transmission of the last block data is finished is determined (Step S28). If the answer is yes, Step S30 is performed to end the flowchart; otherwise, Step S16 is jumped back to.

Please refer to FIG. 8. First, the host gives out a data read-out command (Step S40). Next, the host receives the data from the butters (Step S42). Step S44 of whether there are buffer data stored in the recorder and Step S46 of reading out block data stored in the storage to the buffers are simultaneously performed. In Step S44, if the answer is no, the determination of Step S44 is continued. If the answer is yes, the block data are transmitted to the host bus and then to the host (Step S48). Next, the record of the block data already sent to the storage is erased (Step S50). Subsequently, whether the transmission of the last block data is finished is determined (Step S52). If the answer is yes, Step S54 is performed to end the flowchart; otherwise, Step S44 is jumped back to. After Step S46, the buffer already used is recorded in the record (Step S56). Finally, whether the transmission of the last block data is finished is determined (Step S58). If the answer is yes, Step S60 is performed to end the flowchart; otherwise, Step S46 is jumped back to.

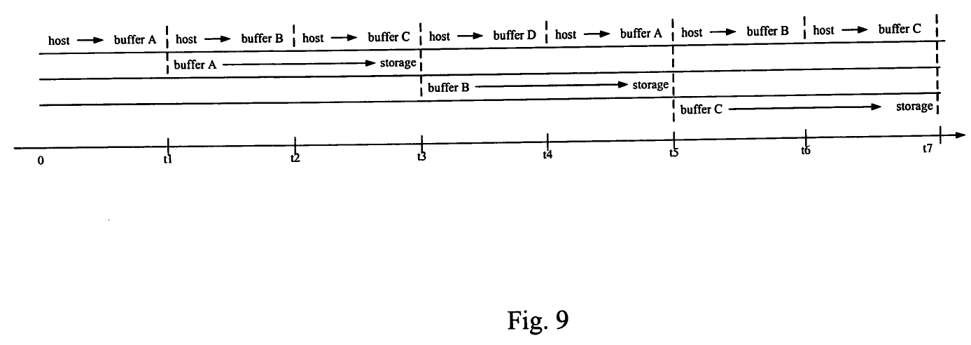

FIG. 9 is a timing diagram of the transmission order of the data storage device having multiple buffers of the present invention. Assuming the data storage device has four buffers: a buffer A, a buffer B, a buffer C and a buffer D. Assuming also that the time for transmitting data from each buffer to the storage is twice that for transmitting data from the host to each buffer. During 0 to t1, the host transmits data to the buffer A. During t1 to t2, the host transmits data to the buffer B. Meanwhile, the transmission of the data temporarily stored in the buffer A to the storage starts. During t2 to t3, the host transmits data to the buffer C. At t3, the transmission of data from the buffer A to the storage is complete, and the buffer B starts to transmit data to the storage. During t3 to t4, the host continues to transmit data to the buffer D. During t4 to t5, the host transmits data to the buffer A again. At t5, the transmission of data from the buffer B to the storage is complete, and the buffer C starts to transmit data to the storage. During t5 to t6, the host continues to transmit data to the buffer B again. During t6 to t7, the host transmits data to the buffer C again. At t7, the transmission of data from the buffer C to the storage is complete. The rest may be deduced by analogy.

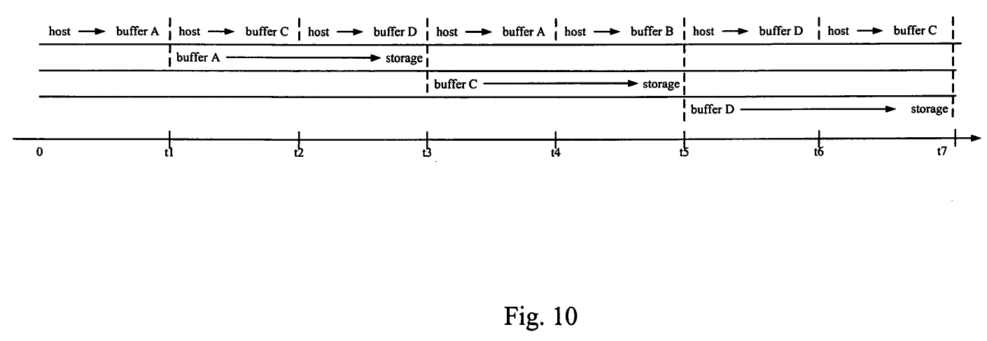

The temporary storage positions in the buffers can be in order, or randomly selected as shown in FIG. 10. When the buffer is empty, data can be stored therein. During 0 to t1, the host transmits data to the buffer A. During t1 to t2, the host transmits data to the buffer C. Meanwhile, the transmission of the data temporarily stored in the buffer A to the storage starts. During t2 to t3, the host transmits data to the buffer D. At t3, the transmission of data from the buffer A to the storage is complete, and the buffer C starts to transmit data to the storage. During t3 to t4, the host transmits data to the buffer A again. During t4 to t5, the host transmits data to the buffer B. At t5, the transmission of data from the buffer C to the storage is complete. During t5 to t6, the host transmits data to the buffer D again, and the transmission of data from the buffer D to the storage starts. During t6 to t7, the host transmits data to the buffer C again. At t7, the transmission of data from the buffer D to the storage is complete. The rest may be deduced by analogy.

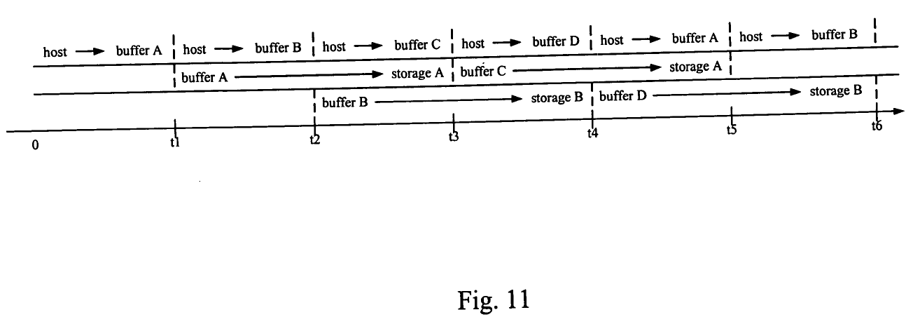

Besides, multiple storages can be installed. FIG. 11 is a timing diagram of the transmission order of the data storage device having four buffers (buffer A, buffer B, buffer C and buffer D) and two storages (storage A and storage B). During 0 to t1, the host transmits data to the buffer A. During t1 to t2, the host transmits data to the buffer B. Meanwhile, the transmission of the data in the buffer A to the storage A starts. During t2 to t3, the host transmits data to the buffer C. At t3, the transmission of data from the buffer A to the storage A is complete, and the buffer B starts to transmit data to the storage B. During t3 to t4, the host transmits data to the buffer D, and the transmission of data in the buffer C to the storage A starts. At t4, the transmission of the data in the buffer B to the storage B is complete. During t4 to t5, the host transmits data to the buffer A again, and the transmission of data in the buffer D to the storage B starts. At t5, the transmission of data from the buffer C to the storage A is complete. During t5 to t6, the host continues to transmit data to the buffer B again. During t6 to t7, the host transmits data to the buffer B again, and the transmission of data in the buffer A to the storage A starts. At t7, the transmission of data from the buffer D to the storage B is complete. The rest may be deduced by analogy.

To sum up, the present invention proposes a data storage device having multiple buffers matched with one or more storages. During data transmission, the host and the storage can transmit data simultaneously to achieve the maximum bandwidth of the transmission interface of the host, hence avoiding the occurrence of idle time and increasing the transmission speed.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A data storage device having multiple buffers comprising:
a host bus for receiving multiple block data sent from a host;
at least three buffers for temporarily storing said data;
at least a storage for storing said data;
a recorder for recording the transmission order and the temporary storage positions of said data in said buffers; and
a controller connected with said host bus, said recorder, said buffers and said storage and used for controlling operations of said host, said recorder, said buffers and said storage.

2. The data storage device having multiple buffers as claimed in claim 1, wherein said controller further has a buffer selector connected with said recorder and said buffers for selecting the temporary storage position of each piece of said data in said buffers.

3. The data storage device having multiple buffers as claimed in claim 1, wherein said controller further has at least a storage selector connected with said storage for selecting storage positions of said buffers.

4. The data storage device having multiple buffers as claimed in claim 1, wherein the transmission order and temporary storage positions are predetermined.

5. The data storage device having multiple buffers as claimed in claim 1, wherein the transmission order and temporary storage positions are randomly selected.

6. The data storage device having multiple buffers as claimed in claim 1, wherein said controller further has at least a storage controller connected with said storage for controlling the operation of said storage.
